(19) United States
(12) Patent Application Publication
(10) Pub. No.: US 2009/0126813 A1
(43) Pub. Date: May 21, 2009

(54) Liquid-Transport Device and System

(75) Inventors: Ichiro Yanagisawa, Saitama-ken (JP); Masana Nishikawa, Tokyo (JP)

Correspondence Address: STEPTOE & JOHNSON LLP, 1330 CONNECTICUT AVENUE, N.W., WASHINGTON, DC, 20036, US

(73) Assignee: Nano Fusion Technologies, Inc., Meguro-ku (JP)

(21) Appl. No.: 11/887,446

(22) PCT Filed: Mar. 30, 2006
(86) PCT No.: PCT/JP2006/306758

§ 371 Date: Sep. 28, 2007

(30) Foreign Application Priority Data
Mar. 30, 2005 (JP) 2005-099234

(51) Int. Cl. B81B 7/02; F04F 99/00; B81B 7/04

(52) U.S. Cl. 137/831; 417/48; 137/827; 137/832

(57) ABSTRACT

An electroosmotic flow pump is filled with a driving liquid exhibiting electroosmotic phenomenon, and a transport liquid capable of noncontact movement through a valve as the driving liquid moves. Since only the driving liquid can pass through an electroosmotic material, even a transport liquid not exhibiting electroosmotic phenomenon can be transported by utilizing the electroosmotic flow pump. Consequently, the electroosmotic flow pump can transport any transport liquid stably so long as the driving liquid exhibits electroosmotic phenomenon.

### TECHNICAL FIELD

The present invention relates to a liquid-transport device and a liquid-transport system for controlling movement of a liquid flowing in a microfluid chip, together with a drug delivery system, or an electronics device, incorporating an electroosmotic pump.

### BACKGROUND ART

The present applicant has heretofore proposed an electroosmotic pump having a size on the order of several tens [mm] to several [mm] for actuating a liquid in a microfluid chip, a drug delivery system, a microelectronics device, or the like.

The electroosmotic pump employs an electroosmotic material having pores therein, such as a porous material, fibers, or the like, for achieving practical flow rate vs. pressure characteristics (several hundreds [μL/min] and several hundreds [kPa]) even under low drive voltages (about 3 [V] to 30 [V]).

Since the electroosmotic pump is capable of providing a high actuating pressure although it is small in size, various applications have been considered (see Patent Documents 1 through 3).

The electroosmotic pump generally has the following merits compared with other mechanical small-size pumps (micropumps).

(1) The electroosmotic pump is capable of producing a pulsation-free flow, which is a large merit compared with other pumps such as diaphragm pumps. Pulsation-free flow is beneficial in applications where very small flow rates are handled, or where a small reverse flow is problematic in joints. Furthermore, although mechanical pumps suffer from debubbling due to cavitation, electroosmotic pumps are free from debubbling problems in principle.

(2) The electroosmotic pump is suitable for high-pressure actuation although it is small in size. For example, it is difficult for a centrifugal pump to produce a pressure of several hundreds [kPa] with a structure on the order of [mm]. However, it is easy for the electroosmotic pump to produce a pressure of several hundreds [kPa] even under a drive voltage of 30 [V]. If the drive voltage is increased, then it is possible to increase the pressure to several tens atm. to several hundreds atm.

(3) Basically, since the electroosmotic pump simply comprises an electroosmotic member and electrodes, and is free of mechanical moving parts, it is highly reliable. Since the electroosmotic pump is simple in structure, it can be manufactured at a reduced cost.

(4) The electroosmotic pump can easily adjust the pump flow rate and the direction of flow by changing the magnitude and polarity of the voltage applied to the electrodes.

Regardless of the above merits, electroosmotic pumps are used as pumps incorporated into capillaries and microfluid chips in limited fields, such as analytical chemistry, biochemistry, etc. This is because an electroosmotic pump is considered to be usable only in applications involving capillaries and microfluid chips. At the present, sufficient efforts have not been made to study other fields, which can make use of an electroosmotic pump having a size on the order of several tens [mm] to several [mm], and which is capable of producing high flow rate vs. high pressure characteristics under application of a low drive voltage.

### Patent Document 1: U.S. Published Application No. 2003/0068229

### Patent Document 2: U.S. Published Application No. 2004/0234378

Patent Document 3: U.S. Pat. No. 3,923,426

### DISCLOSURE OF THE INVENTION

Fluids that can directly be actuated by the electroosmotic pump are limited. This is because the electroosmotic pump actuates a fluid based on electroosmosis, and electroosmotic functions based on an electrochemical phenomenon at an interface between the electroosmotic member and the liquid. It is difficult to actuate a liquid in which an electrochemical phenomenon does not occur.

Actuation of an aqueous solution based on electroosmosis on the surface of a glass tube shall be described below.

When the glass tube is filled with an aqueous solution, a silanol group existing on the surface of the glass tube is dissociated as a result of a chemical reaction between the water and the glass surface, thereby negatively charging the surface of the glass tube. For canceling negative charges on the glass surface, counter ions (in this case positive ions) in the water gather in the vicinity of the glass surface. Negative charges on the glass surface cannot move, whereas positive ions are movable. As a result, when an electric field is applied in the direction of the tube passage in the glass tube, the positive ions are moved in the direction of the electric field. Water around the positive ions is moved as a result of being dragged by the positive ions, due to the viscosity of the water. The water flow is an electroosmotic flow.

In order for a certain liquid to exhibit electroosmosis, it is essential for the material making up the tube passage through which the liquid passes to be electrically charged. In other words, the potential on the surface of the material (zeta potential) needs to be sufficiently high. The degree to which the material making up the tube passage is electrically charged depends not only on the type of liquid, but also the pH, etc., thereof. Consequently, there are liquids that are suitable for being actuated by electroosmotic pumps and other liquids that are not.

For example, if the electroosmotic material is glass, when a strong acid is caused to flow through a glass tube passage, it is difficult to produce an electroosmotic flow, since the zeta potential is low. A liquid, which contains a surfactant, which combines with a dissociated silanol group, or which contains counter ions adsorbed into the surface of the tube passage, is not suitable for being actuated by such an electroosmotic pump.

Liquids that are of good electrical conductivity are also not suitable for being actuated by the electroosmotic pump, since the current flowing between the electrodes becomes excessive, thereby degrading pump efficiency and producing gas.

The electroosmotic member is made of a porous material, fibers, fine particles, or the like, which provide a fluid passage ranging from several tens [μm] to several tens [nm]. Therefore, substances having sizes that cannot pass through the fluid passage (e.g., cells, white blood cells, red blood cells), as well as substances that are likely to be adsorbed by the electroosmotic member (e.g., proteins), are difficult to actuate directly.

As described above, electroosmotic pumps suffer from various limitations with respect to fluids that can be actuated thereby, and such limitations present significant obstacles on efforts to increase the range of applications for electroosmotic pumps.

An object of the present invention is to provide a liquid feeding device and a liquid transport system, which are capable of transporting liquids of any type, by means of an improvement in the above electroosmotic pump.

A liquid transport device according to the present invention includes a first electrode and a second electrode disposed upstream and downstream, respectively, from an electroosmotic member disposed in a fluid passage, wherein when a voltage is applied to the first electrode and the second electrode, a drive liquid is caused to flow within the fluid passage through the electroosmotic member, characterized in that at least a portion of an upstream side of the electroosmotic member serves as a drive liquid reservoir filled with the drive liquid, at least a portion of a downstream side of the electroosmotic member serves as a transport liquid reservoir filled with a transport liquid, which can be supplied to an external device as the drive liquid moves, a liquid isolating means for isolating the drive liquid and the transport liquid from each other is interposed between the drive liquid and the transport liquid, and wherein when the voltage is applied, the drive liquid supplies or draws the transport liquid through the liquid isolating means.

With the above arrangement, the liquid transport device is filled with the drive liquid, which exhibits electroosmosis, as well as the transport liquid, which is movable as the drive liquid moves, with the liquid isolating means keeping the transport liquid out of contact with the drive liquid. The transport liquid can be transported by the liquid transport device, even if the transport liquid is a liquid that does not exhibit electroosmosis. Therefore, the liquid transport device can stably transport the transport liquid, irrespective of the type of liquid that constitutes the transport liquid, insofar as the drive liquid is a liquid which exhibits electroosmosis. Since the drive liquid and the transport liquid are separated from each other by the liquid isolating means, they are not brought into contact with each other and do not intermix, and thus the transport liquid can be transported reliably.

If the fluid passage has a diameter ranging from 2 to 3 mm or less, where surface tension is more dominant than gravitation as a force acting on the drive liquid and the transport liquid within the fluid passage, the liquid isolating means should preferably comprise a gas that resides downstream of the electroosmotic member. The drive liquid and the transport liquid can thus be separated from each other by means of a simple arrangement.

The liquid isolating means should preferably be made of a hydrophobic material, which is capable of passing gas therethrough, while preventing the drive liquid and the transport liquid from passing through the liquid isolating means. The drive liquid and the transport liquid can thus be separated from each other by the gas and by the liquid isolating means, which is made of a hydrophobic material.

At least one of the drive liquid reservoir and the transport liquid reservoir should preferably comprise a structure that is removable from the liquid transport device. Thus, components of the liquid transport system can be unitized.

The transport liquid reservoir should preferably comprise a microfluid chip. Thus, actuation of a relatively large amount of liquid to be delivered can be controlled using the liquid transport device.

A liquid transport system according to the present invention incorporates the liquid transport devices described above. The liquid transport system comprises a plurality of liquid filling lines for filling transport liquid reservoirs of respective liquid transport devices with the transport liquid, a plurality of liquid supply lines for supplying the transport liquid from the transport liquid reservoirs to an external device, and a plurality of valves disposed in the liquid filling lines and the liquid supply lines, wherein the valves are selectively opened and closed to alternately fill the transport liquid reservoirs with the transport liquid from the liquid filling lines, and to supply the transport liquid from the transport liquid reservoirs to the liquid supply lines, for thereby supplying the transport liquid to the external device or for drawing the transport liquid from the external device at all times.

With the above arrangement, since plural liquid transport devices are connected in parallel to each other so as to supply or draw the transport liquid, a large amount of transport liquid can continuously be supplied or drawn.

### BRIEF DESCRIPTION OF THE DRAWINGS

FIG. 1 is a cross-sectional view of an electroosmotic pump according to a first embodiment;

FIG. 2 is a cross-sectional view of a modification of the electroosmotic pump shown in FIG. 1;

FIG. 3 is a cross-sectional view of an electroosmotic pump according to a second embodiment;

FIG. 4 is a cross-sectional view of an electroosmotic pump according to a third embodiment;

FIG. 5 is a cross-sectional view of an electroosmotic pump according to a fourth embodiment;

FIG. 6 is a cross-sectional view of an electroosmotic pump according to a fifth embodiment;

FIG. 7 is a cross-sectional view of an electroosmotic pump according to a sixth embodiment;

FIG. 8 is a cross-sectional view of another structure of the electroosmotic pump shown in FIG. 7;

FIG. 9 is a cross-sectional view of an electroosmotic pump according to a seventh embodiment;

FIG. 10 is an exploded perspective view of a transport liquid reservoir shown in FIG. 9;

FIG. 11 is a block diagram of a liquid transport system, incorporating the electroosmotic pumps shown in FIGS. 1 through 10;

FIG. 12 is a timing chart illustrating operations of the liquid transport system shown in FIG. 11; and

FIG. 13 is a timing chart illustrating operations of the liquid transport system shown in FIG. 11.

### BEST MODE FOR CARRYING OUT THE INVENTION

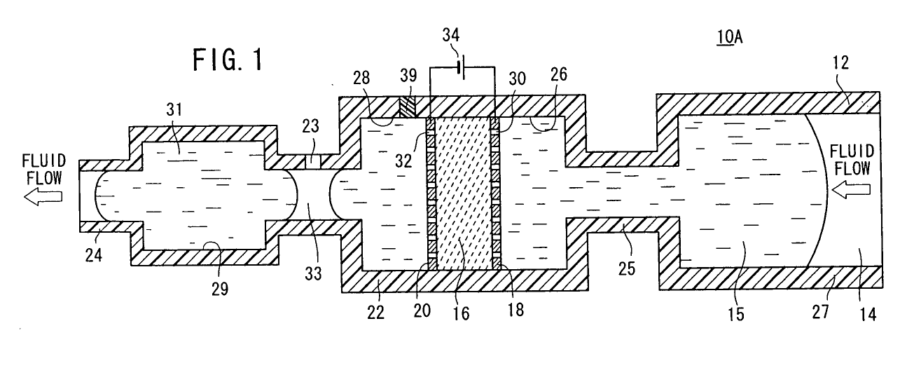

An electroosmotic pump (liquid transport device) 10A according to a first embodiment is a small-size pump, having a size in the range of from several [mm] to several [cm], such that the pump can be installed on a microfluid chip or a small-size electronics device for use in biotechnology and analytic chemistry. As shown in FIG. 1, the electroosmotic pump 10A basically comprises a pump casing 12, an electroosmotic member 16 disposed in a fluid passage 14 defined in the pump casing 12, an inlet electrode (first electrode) 18, and an outlet electrode (second electrode) 20.

The pump casing 12 is made of a plastic material, which is resistant to a drive liquid 15 comprising an electrically conductive fluid such as an electrolytic solution or the like, and which passes through the fluid passage 14. The pump casing 12 may also be made of ceramics, glass, or a metal material having an electrically insulated surface. The pump casing 12 includes a large-diameter portion 22, in which the electroosmotic member 16, the inlet electrode 18 and the outlet electrode 20 are disposed, and small-diameter portions 24, 25 disposed upstream and downstream from the large-diameter portion 22. The drive liquid 15 is a liquid that exhibits electroosmosis, which passes through the fluid passage 14 from the right (the small-diameter portion 25) to the left (the small-diameter portion 24) in FIG. 1.

The electroosmotic member 16 divides the fluid passage 14 into a region upstream (on the right in FIG. 1) from the electroosmotic member 16 forming an inlet chamber 26, and a region downstream from the electroosmotic member 16 forming an outlet chamber 28. The electroosmotic member 16 is made of porous ceramics, glass fibers, etc. The electroosmotic member 16 is of a hydrophilic nature, such that when the inlet chamber 26 is supplied with the drive liquid 15, the electroosmotic member 16 absorbs and becomes impregnated with the drive liquid 15, and then discharges the drive liquid 15 into the outlet chamber 28.

The inlet electrode 18 is disposed in the inlet chamber 26 in contact with a surface of the electroosmotic member 16, and includes a plurality of pores 30 defined therein along the axial direction of the fluid passage 14. The outlet electrode 20 is disposed in the outlet chamber 28 in contact with a surface of the electroosmotic member 16, and similarly includes a plurality of pores 30 defined therein along the axial direction of the fluid passage 14. The inlet electrode 18 and the outlet electrode 20 are electrically connected to a DC power supply 34. In FIG. 1, the inlet electrode 18 serves as a positive electrode and the outlet electrode 20 serves as a negative electrode. However, the inlet electrode 18 may serve as a negative electrode and the outlet electrode 20 as a positive electrode. In FIG. 1, the electrodes 18, 20 are disposed on surfaces of the electroosmotic member 16. However, the electrodes 18, 20 are not limited to such a layout, and may be disposed near the electroosmotic member 16 out of contact therewith.

A large-diameter portion (drive liquid reservoir) 27 filled with the drive liquid 15 is disposed upstream of the small-diameter portion 25. The drive liquid 15 is supplied from the large-diameter portion 27 to the inlet chamber 26 and permeates the electroosmotic member 16 through the pores 30. When the DC power supply 34 applies a DC voltage to the electrodes 18, 20, the drive liquid 15 impregnated within the electroosmotic member 16 moves in a direction from the inlet electrode 18 toward the outlet electrode 20, and then is discharged through the pores 32 into the outlet chamber 28.

The small-diameter portion 24 on a downstream side of the fluid passage 14 is connected to a fluid passage of a fluid device such as a microfluid chip or the like on a downstream side thereof. A central region of the small-diameter portion 24 forms a large-diameter portion (transport liquid reservoir) 29, which is filled with a transport liquid 31. A bubble 33 serving as a liquid isolating means is interposed between the transport liquid 31 and the drive liquid 15, which is discharged into the outlet chamber 28.

The fluid passages 14, 24, 29, 33 have widths equal to or smaller than about a capillary length (normally 2 to 3 mm). As a result, as a force that acts on the drive liquid 15 and the transport liquid 31, surface tension is more dominant than gravitation. When the drive liquid 15 is discharged into the outlet chamber 28, the transport liquid 31 is pressed downstream by the bubble 33, and thus the transport liquid 31 can be moved into the fluid passage of the fluid device.

The transport liquid 31 is a liquid that can be transported indirectly from the electroosmotic pump 10A to the fluid device while the drive liquid 15 is moved by electroosmosis. The transport liquid 31 may be any type of liquid, insofar as it conforms with the material of the pump casing 12.

The pump casing 12 has an inner wall, which should preferably be hydrophobic. If the width of the fluid passage 14 is equal to or greater than the capillary length, or if the drive liquid 15 is highly impregnating, then it is imperative that the inner wall have a hydrophobic surface, so as to reliably isolate the drive liquid 15 and the transport liquid 31 from each other by the bubble 3.

In FIG. 1, the large-diameter portion 27, which forms a part of the inlet chamber 26, serves as the drive liquid reservoir for the drive liquid 15. However, the inlet chamber 26 may serve in its entirety as a drive liquid reservoir. Alternatively, a supply tank, not shown, for the drive liquid 15, which is connected to the inlet chamber 26, may serve as a drive liquid reservoir.

The large-diameter portion 29, which forms part of the outlet chamber 28, serves as the transport liquid reservoir. However, the outlet chamber 28 may serve in its entirety as a transport liquid reservoir. Alternatively, the outlet chamber 28 may have a straight shape, wherein a downstream side thereof serves as a transport liquid reservoir.

In FIG. 1, the transport liquid 31 is transported to the downstream fluid device. However, when the polarity of the DC power supply 34 is changed, the drive liquid 15 is displaced upstream, causing the bubble 33 to move the transport liquid 31 from the fluid device into the large-diameter portion 29. The electroosmotic pump 10A thus is capable of both supplying and retrieving the transport liquid 31.

The electroosmotic pump 10A according to the first embodiment is filled with the drive liquid 15, which exhibits electroosmosis, and the transport liquid 31, which is movable along with the bubble 33 while remaining out of contact with the drive liquid 15 as the drive liquid 15 moves. Since only the drive liquid 15 passes through the electroosmotic member 16, the transport liquid 31 can be transported by the electroosmotic pump 10A even if the transport liquid 31 is a liquid that does not exhibit electroosmosis. Therefore, the electroosmotic pump 10A can stably transport the transport liquid 31, no matter what type of liquid the transport liquid 31 is, insofar as the drive liquid 15 is a liquid that exhibits electroosmosis. Since the drive liquid 15 and the transport liquid 31 are separated from each other by the bubble 33, the respective liquids are not brought into contact with each other and do not intermix. Therefore, the transport liquid 31 can be transported reliably.

The electroosmotic pump 10A according to the first embodiment can fill the transport liquid reservoir with the transport liquid 31 by any of the following five processes:

(1) The drive liquid 15 is delivered into the transport liquid reservoir (the position where air is left downstream of the small-diameter portion 24, e.g., a distal end portion downstream of the large-diameter portion 29), and the downstream side of the small-diameter portion 24 is immersed in the transport liquid 31. Then, a DC voltage is applied to the electrodes 18, 20 to draw the transport liquid 31 into the transport liquid reservoir. When the liquid level position of the drive liquid 15 is moved to and reaches the boundary between the large-diameter portion 22 and the small-diameter portion 24, application of voltage to the electrodes 18, 20 is stopped. The transport liquid 31 now fills the transport liquid reservoir with the bubble 33 interposed between the transport liquid 31 and the drive liquid 15. In (1), DC voltage is applied such that the electrode 18 acts as a negative electrode and the electrode 20 acts as a positive electrode.

(2) A hole 23 (see FIG. 1) for bleeding air and pouring the transport liquid 31 is formed in a side wall of the pump casing 12 (upstream of the small-diameter portion 24). After the transport liquid 31 has been introduced to fill the transport liquid reservoir through the hole 23, the hole 23 is sealed. The hole 23 has a hydrophobic surface, and is sealed by an adhesive seal member bonded to the hole 23.

(3) If the electroosmotic member 16 is not wetted by the drive liquid 15, then air can be released upstream through the electroosmotic member 16. Therefore, even if an air bleeding hole is not provided, the transport liquid 31 can be introduced to fill the transport liquid chamber while air in the fluid passage 14 is being discharged through the electroosmotic member 16 upstream of the pump.

(4) If a gas bleeding member 39 is provided in a side wall of the pump casing 12 around the outlet chamber 28, then the transport liquid 31 can be introduced to fill the transport liquid chamber by discharging air in the outlet chamber 28 through the gas bleeding member 39, as follows:

First, the drive liquid 15 in the outlet chamber 28 is drawn into the drive liquid reservoir, while keeping the gas bleeding member 39 unwetted by the drive liquid 15. However, this process may be dispensed with if the electroosmotic member 16 itself is not wetted by the drive liquid 15. Then, the transport liquid reservoir is filled with the transport liquid 31 using a syringe or the like.

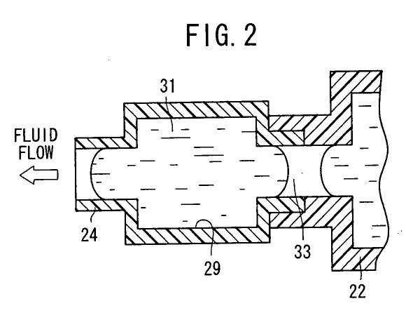

(5) As shown in FIG. 2, the small-diameter portion 24 and the large-diameter portion 22 are separated from each other. With the small-diameter portion 24 and the large-diameter portion 22 being spaced from each other in this manner, the transport liquid 31 is introduced to fill the large-diameter portion 29 that serves as the transport liquid reservoir, and while the upstream side of the small-diameter portion 24 is not filled with the transport liquid 31 (it is filled only with air), the small-diameter portion 24 and the large-diameter portion 22 are brought into interfitting engagement with each other. The air serves as the bubble 33, such that the transport liquid 31 can be actuated by the drive liquid 15 through the bubble 33. According to the filling process (5), the electroosmotic pump 10A does not have to be activated in advance.

In the electroosmotic pump 10A, the electrodes 18, 20 are shaped as electrodes having pores 30, 32 defined therein. However, wire-shaped electrodes, or electrodes each in the form of a porous body the surface of which is evaporated with a metal, may also be employed. The electrodes 18, 20 preferably should be made of an electrically conductive material, such as platinum, carbon, silver, or the like.

The electrode 18 serves as a positive electrode and the electrode 20 serves as a negative electrode. However, as described above, the electrode 18 also may serve as a negative electrode, and the electrode 20 may serve as a positive electrode, wherein the above operations and advantages may also be achieved.

Although a DC voltage is applied to the electrodes 18, 20, a pulsed voltage may also be applied to the electrodes 18, 20.

In the electroosmotic pump 10A, the pump casing 12 includes the large-diameter portion 22 and the small-diameter portion 24, which are successively arranged in this order from the upstream side. However, the pump casing 12 is not limited to the above configuration. The pump casing 12 may have a straight shape as a whole, or may include a small-diameter portion and a large-diameter portion, which are successively arranged in this order from the upstream side.

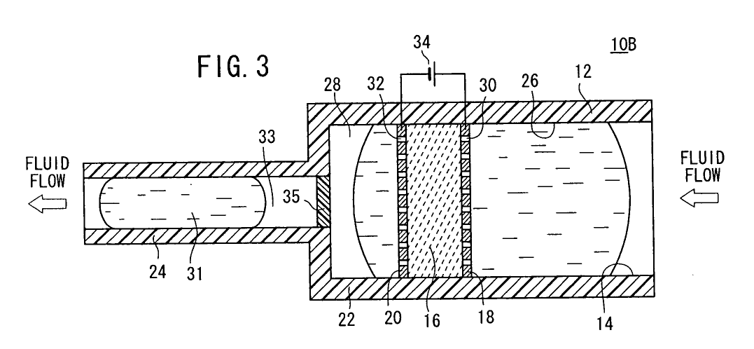

An electroosmotic pump 10B according to a second embodiment shall be described below with reference to FIG. 3. Those components of the electroosmotic pump 10B that are identical to those of the electroosmotic pump 10A according to the first embodiment shown in FIGS. 1 and 2 shall be denoted using identical reference characters. This also holds true for other embodiments.

As shown in FIG. 3, the electroosmotic pump 10B according to the second embodiment differs from the electroosmotic pump 10A according to the first embodiment (see FIGS. 1 and 2) in that the drive liquid 15 and the transport liquid 31 are separated from each other by a hydrophobic gas-permeable membrane 35 as well as by the bubble 33 in the outlet chamber 28.

As the electroosmotic pump 10B operates, when the drive liquid 15 moves downstream inside the fluid passage 14, the bubble 33 in the outlet chamber 28 passes through the gas-permeable membrane 35 and presses on the transport liquid 31 so as to move the transport liquid 31 downstream. Therefore, both the bubble 33 and the gas-permeable membrane 35 reliably separate the drive liquid 15 and the transport liquid 31 from each other. If the drive pressure of the electroosmotic pump 10B is equal to or smaller than the minimum water breakthrough point of the gas-permeable membrane 35 (i.e., a minimum pressure required for the drive liquid 15 or the transport liquid 31 to pass through the gas-permeable membrane 35), then the drive liquid 15 and the transport liquid 31 can be more reliably prevented from coming into contact with each other. In FIG. 3, the inlet chamber 26 serves in its entirety as the drive liquid reservoir.

A process for introducing the transport liquid 31 to fill the transport liquid reservoir in the electroosmotic pump 10B according to the second embodiment is as follows: First, the drive liquid 15 is pushed out to fill the portion of the outlet chamber 28 with the drive liquid 15 up to the gas-permeable membrane 35. Then, the downstream side of the small-diameter portion 24 is immersed in the transport liquid 31 while a DC voltage is applied to the electrode 18, which acts as a negative electrode, and the electrode 20, which acts as a positive electrode. The drive liquid 15 moves upstream in order to draw the transport liquid 31 into the transport liquid reservoir. In this case, the transport liquid 31 can be drawn or delivered in a quantity that corresponds to the volume of space from the gas-permeable membrane 35 in the outlet chamber 28 up to the electroosmotic member 16.

Naturally, the electroosmotic pump 10B can employ any of the filling processes (2) through (5) described above in connection with the electroosmotic pump 10A according to the first embodiment.

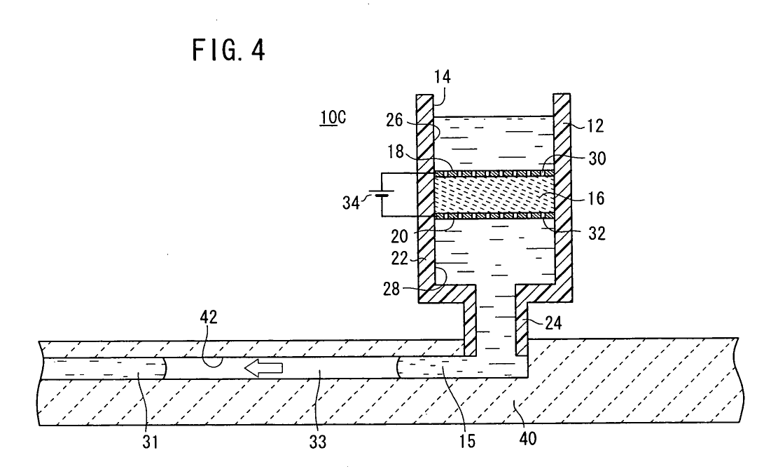

An electroosmotic pump 10C according to a third embodiment shall be described below with reference to FIG. 4.

As shown in FIG. 4, the electroosmotic pump 10C according to the third embodiment differs from the electroosmotic pumps 10A, 10B according to the first and second embodiments (see FIGS. 1 through 3) in that the electroosmotic pump 10C has a downstream end thereof connected to a microfluid chip 40.

The microfluid chip 40, which is connected to the downstream end of the fluid passage 14 of the electroosmotic pump 10C, serves as a transport liquid reservoir for the transport liquid 31. As with the electroosmotic pump 10A according to the first embodiment (see FIGS. 1 and 2), when the drive liquid 15 moves into the fluid passages 14, 42, the transport liquid 31 is moved, with the bubble 33 being interposed between the drive liquid and the transport liquid 31. Therefore, movement of the transport liquid 31 inside the microfluid chip 40 can easily be controlled by the electroosmotic pump 10C.

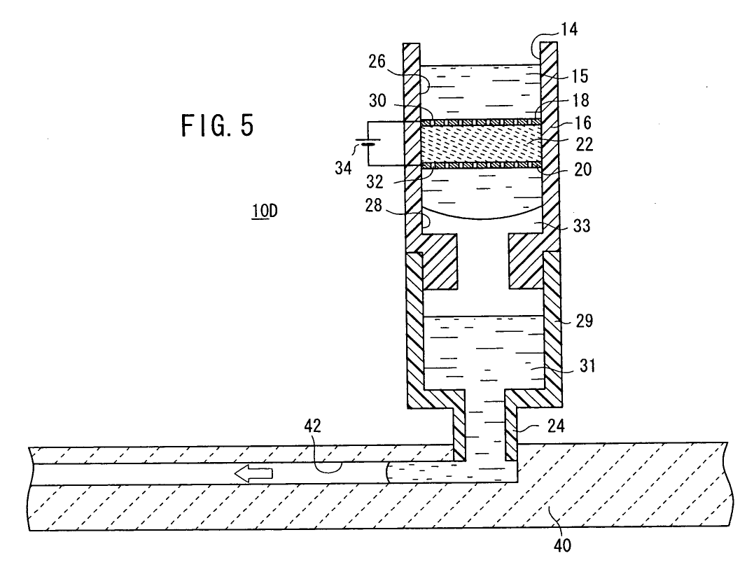

An electroosmotic pump 10D according to a fourth embodiment shall be described below with reference to FIG. 5.

As shown in FIG. 5, the electroosmotic pump 10D according to the fourth embodiment differs from the electroosmotic pumps 10A through 10C according to the first through third embodiments (see FIGS. 1 through 3) in that the large-diameter portion 29, serving as the transport liquid reservoir, is separable from the portion upstream of the large-diameter portion 29.

By filling the large-diameter portion 29 with the transport liquid 31, liquids that heretofore could not be introduced directly into the microfluid chip 40 can be delivered directly into the microfluid chip 40 by means of the electroosmotic pump 10D. The electroosmotic pump 10D is suitable for use in applications where the total amount of the transport liquid 31 is several [μL] or the like.

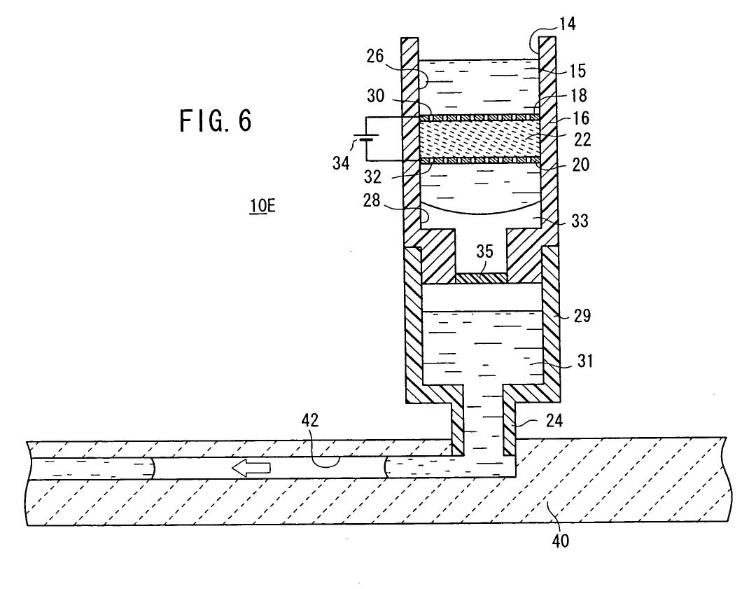

An electroosmotic pump 10E according to a fifth embodiment shall be described below with reference to FIG. 6.

As shown in FIG. 6, the electroosmotic pump 10E according to the fifth embodiment differs from the electroosmotic pump 10D according to the fourth embodiment (see FIG. 5) in that a gas-permeable membrane 35 is disposed in the outlet chamber 28.

As with the electroosmotic pump 10B according to the second embodiment (see FIG. 3), the bubble 33 and the gas-permeable membrane 35 can reliably separate the drive liquid 15 and the transport liquid 31 from each other. Further, if the drive pressure of the electroosmotic pump 10F is equal to or smaller than the minimum water breakthrough point of the gas-permeable membrane 35, the drive liquid 15 and the transport liquid 31 are more reliably prevented from coming into contact with each other.

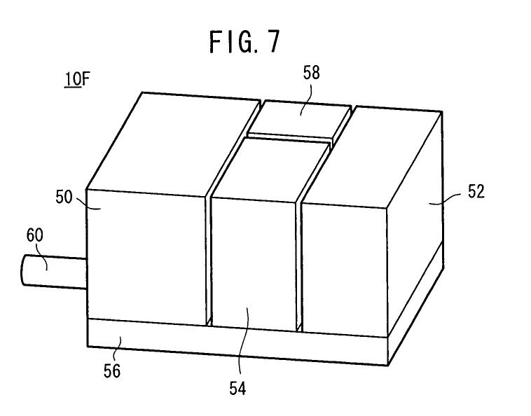

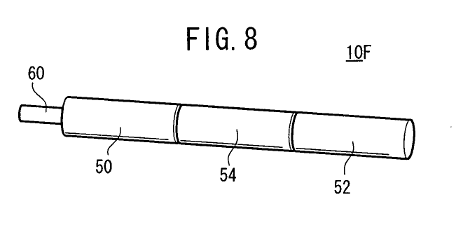

An electroosmotic pump 10F according to a sixth embodiment shall be described below with reference to FIGS. 7 and 8.

As shown in FIGS. 7 and 8, the electroosmotic pump 10F according to the sixth embodiment differs from the electroosmotic pumps 10A through 10E according to the first through fifth embodiments (see FIGS. 1 through 6) in that a transport liquid reservoir 50 and a drive liquid reservoir 52 are formed as unitized structures, which are removable from the electroosmotic pump 10F.

With the electroosmotic pumps 10A through 10E according to the first through fifth embodiments, the transport liquid reservoir and the drive liquid reservoir are of a built-in integral structure incorporated into the pump. The electroosmotic pumps 10A through 10E are suitable for use in applications where the total amount of the transport liquid 31 and the drive liquid 15 is several tens [μL] or the like. If larger quantities (e.g., 100 [μL] or greater) of the transport liquid 31 and the drive liquid 15 are handled, then since the transport liquid reservoir has a large size compared with the size of the pump itself, such an integral structure for the transport liquid reservoir and the drive liquid reservoir becomes less advantageous.

The electroosmotic pumps 10A through 10E are suitable for use as portable or disposable liquid feeding devices, since they are inexpensive and small in size. In some occasions, however, the pump itself needs to be reused.

With the electroosmotic pump 10F, both the transport liquid reservoir 50 and the drive liquid reservoir 52 have a removable unitized structure, so that a pump body 54 of the electroosmotic pump 10F may be reused, whereas the transport liquid reservoir 50 and the drive liquid reservoir 52 are disposable, or wherein the transport liquid reservoir 50 and the drive liquid reservoir 52 may be reused by filling them respectively with the transport liquid 31 and the drive liquid 15. The transport liquid reservoir 50 preferably comprises, for example, a general liquid container, a tube, or a microfluid chip.

FIG. 7 shows the electroosmotic pump 10F, including the transport liquid reservoir 50, the drive liquid reservoir 52, the pump body 54, and a battery 58 for actuating the pump body 54, all fixedly mounted on a board 56. The electroosmotic pump 10F is suitable for use as a reservoir unit having a relatively large capacity. The transport liquid reservoir 50 also has a liquid delivery port 60.

FIG. 8 shows a structure suitable for use as a reservoir unit, and which has a capacity smaller than that of the reservoir unit shown in FIG. 7. The structure includes a transport liquid reservoir 50 formed in a cylindrical shape, the pump body 54, and the drive liquid reservoir 52, which are connected in succession. Each of these components forms a unit, having a diameter ranging from 5 [mm] to 10 [mm] and a length ranging from 10 to 20 [mm].

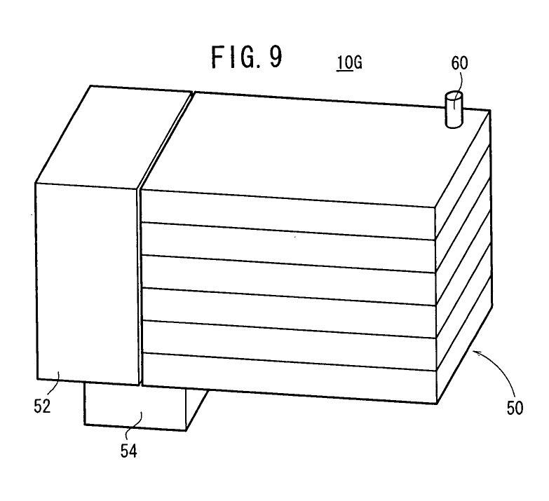

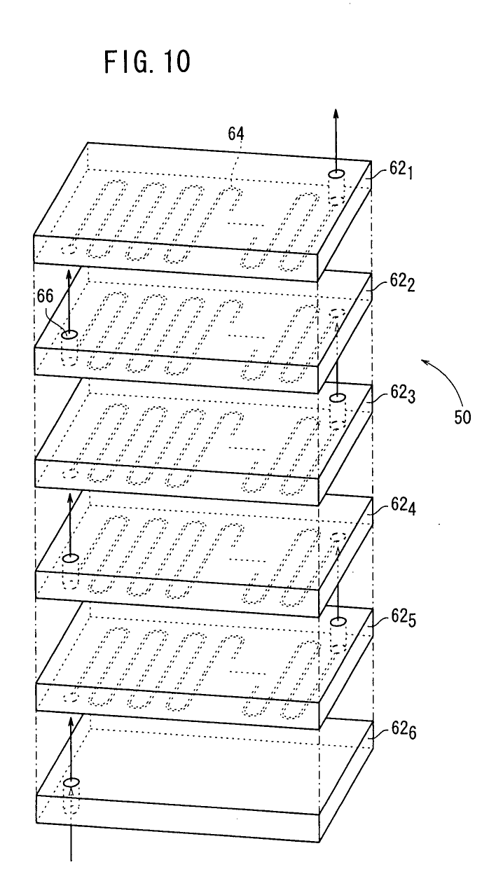

An electroosmotic pump 10G according to a seventh embodiment shall be described below with reference to FIGS. 9 and 10.

As shown in FIGS. 9 and 10, the electroosmotic pump 10G according to the seventh embodiment differs from the electroosmotic pump 10F according to the sixth embodiment (see FIGS. 7 and 8) in that the transport liquid reservoir 50 comprises a stacked structure of microfluid chips.

As shown in FIG. 10, the transport liquid reservoir 50 comprises a vertical stack of boards 62ᵢ (i=1 through 6), including five boards 62₁ through 62₅ from above, which have meandering grooves (hereinafter also referred to as fluid passages) 64 defined in bottom portions thereof. Connection holes 66 are defined in opposite ends of the grooves 64 and the substrate 62₆. When the boards 62ᵢ are stacked together, the grooves 64 are interconnected, for allowing the transport liquid 31 to pass therethrough and for providing an increased liquid filling ratio.

If the fluid passages 64, each having a depth of 200 [μm] and a width of 500 [μm], are defined at an interval of 500 [μm] in each of the boards 62ᵢ having a thickness of 0.5 [mm], then the filling ratio of the transport liquid 31 with respect to the volume of the microfluid chip is about 20%.

If a required inventory of the transport liquid 31 is 5 [mL], then the transport liquid reservoir 50 has a volume of about 33 [mL]. Such a volume can be realized by stacking 6 or 7 boards 62ᵢ, each having a size of 3 [cm]×4 [cm]×0.5 [mm].

The drive liquid reservoir 52 may be of a general cartridge structure.

Exemplary specifications for the electroosmotic pump 10G shall be described below. The transport liquid reservoir 50 has a volume of 5 [mL], the drive liquid reservoir 52 has a volume of 5 [mL], and the pump body has a drive voltage of 12 [V] and a supply rate of 1 [μL/min]. The electroosmotic pump 10G has a continuous operation time of 80 hours, an overall volume of about 60 [mL], and a weight of about 100 [g].

As with the electroosmotic pumps 10A through 10F according to the first through sixth embodiments (see FIGS. 1 through 8), the electroosmotic pump 10G according to the seventh embodiment should preferably be of a type that supplies or draws the transport liquid 31 based on the drive liquid 15, with the bubble 33 being interposed between the transport liquid 31 and the drive liquid 15.

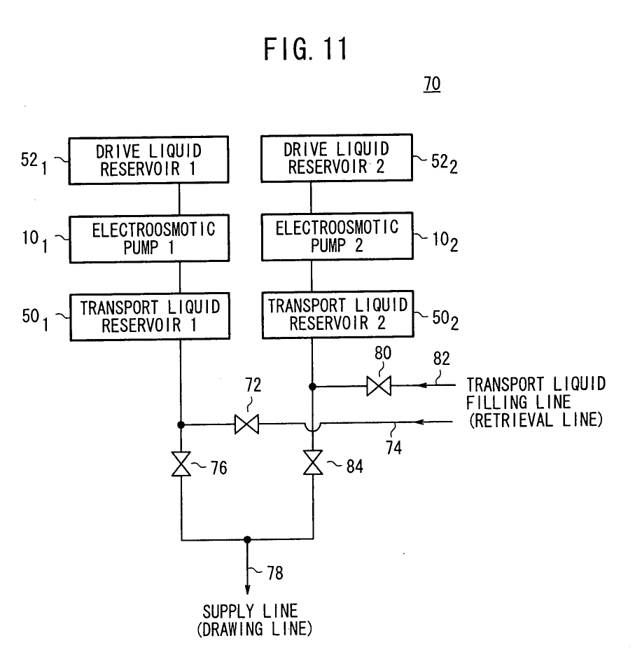

A liquid transport system 70 incorporating the electroosmotic pumps 10A through 10G according to the first through seventh embodiments (see FIGS. 1 through 10) shall be described below with reference to FIGS. 11 through 13.

The liquid transport system 70 comprises a plurality of parallel-connected electroosmotic pumps 10_{I} (I=1 through n) for continuously actuating a large quantity of the transport liquid 31. FIG. 11 shows the liquid transport system 70, which includes two parallel-connected electroosmotic pumps 10₁, 10₂ operated continuously.

The electroosmotic pump 10₁ is connected to a transport liquid filling line (or transport liquid retrieval line) 74 through a valve 72, and also is connected to a transport liquid supply line (or transport liquid drawing line) 78 through a valve 76. The electroosmotic pump 10₂ is connected to a transport liquid filling line (or transport liquid retrieval line) 82 through a valve 80, and also is connected to the transport liquid supply line 78 through a valve 84. Each of the electroosmotic pumps 10_{I} includes upstream and downstream sides, which are connected respectively to a drive liquid reservoir 52_{I} and a transport liquid reservoir 50_{I}.

In the liquid transport system 70, directions in which the electroosmotic pumps 10_{I} are actuated are alternately changed, while the valves 72, 76, 80, 84 are operated in synchronism with changing of the driving directions of the electroosmotic pumps 10_{I}, so as to keep the drive liquid 15 and the transport liquid 31 out of contact with each other, and to continuously deliver the transport liquid 31 to the transport liquid supply line 78.

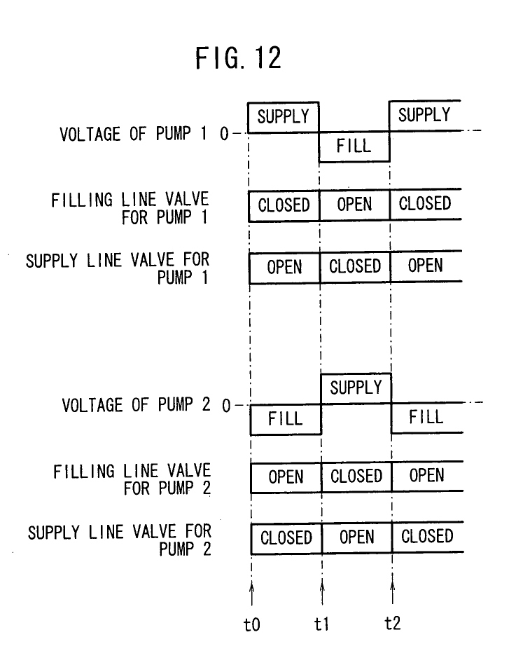

Specifically, as shown in FIGS. 11 and 12, at time t0, the valve 72 is closed and the valve 76 is opened, and the electroosmotic pump 10₁ is actuated in order to move the drive liquid 15 that has filled the drive liquid reservoir 52₁ into the transport liquid reservoir 50₁, thereby delivering the transport liquid 31 that has filled the transport liquid reservoir 50₁ to the transport liquid supply line 78.

On the other hand, at time t0, the valve 84 is closed and the valve 80 is opened, and the electroosmotic pump 10₂ is actuated in order to move the drive liquid 15 into the drive liquid reservoir 52₂, thereby causing the transport liquid 31 from the transport liquid filling line 82 to fill the transport liquid reservoir 50₂.

Next, at time t1, the valve 72 is opened and the valve 76 is closed, and the electroosmotic pump 10₁ is actuated in order to move the drive liquid 15 to the drive liquid reservoir 52₁, thereby causing the transport liquid 31 from the transport liquid filling line 74 to fill the transport liquid reservoir 50₁.

On the other hand, at time t1, the valve 84 is opened and the valve 80 is closed, and the electroosmotic pump 10₂ is actuated in order to move the drive liquid 15 that has filled the drive liquid reservoir 52₂ into the transport liquid reservoir 50₂, thereby delivering the transport liquid 31 that has filled the transport liquid reservoir 50₂ to the transport liquid supply line 78.

At time t2, the liquid transport system 70 repeats the operations performed at time t0.

In the liquid transport system 70, furthermore, the directions in which the electroosmotic pumps 10_{I} are actuated are alternately changed, whereby the valves 72, 76, 80, 84 are operated in synchronism with changing the driving directions of the electroosmotic pumps 10_{I}, so as to keep the drive liquid 15 and the transport liquid 31 out of contact with each other and to continuously draw the transport liquid 31 from an external source via the transport liquid supply line 78, as well as to retrieve the transport liquid 31 through the transport liquid retrieval lines 74, 82.

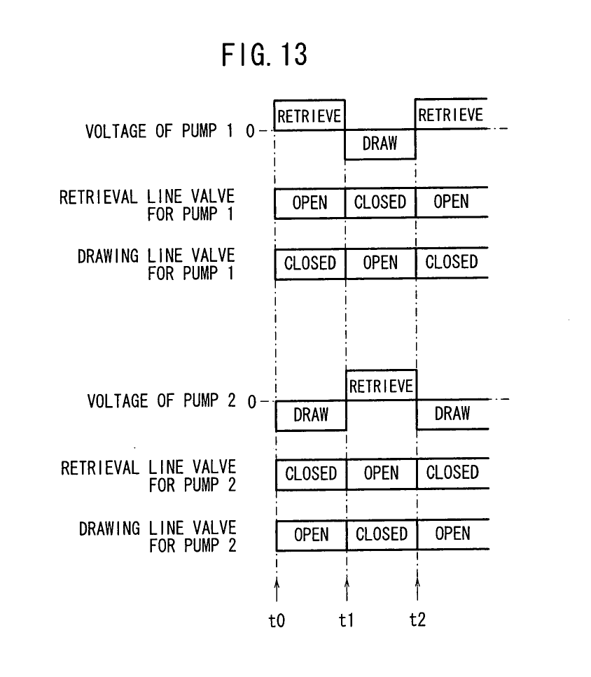

Specifically, as shown in FIGS. 11 and 13, at time t0, the valve 72 is opened and the valve 76 is closed, and the electroosmotic pump 10₁ is actuated in order to move the drive liquid 15 that has filled the drive liquid reservoir 52₁ into the transport liquid reservoir 50₁, thereby retrieving the transport liquid 31 that has been drawn into the transport liquid reservoir 50₁ through the transport liquid retrieval line 74.

On the other hand, at time t0, the valve 84 is opened and the valve 80 is closed, and the electroosmotic pump 10₂ is actuated in order to move the drive liquid 15 into the drive liquid reservoir 52₂, thereby drawing the transport liquid 31 from the transport liquid drawing line 78 into the transport liquid reservoir 50₂.

Next, at time t1, the valve 72 is closed and the valve 76 is opened, and the electroosmotic pump 10₁ is actuated in order to move the drive liquid 15 into the drive liquid reservoir 52₁, thereby drawing the transport liquid 31 from the transport liquid drawing line 78 into the transport liquid reservoir 50₁.

On the other hand, at time t1, the valve 84 is closed and the valve 80 is opened, and the electroosmotic pump 10₂ is actuated in order to move the drive liquid 15 that has filled the drive liquid reservoir 52₂ into the transport liquid reservoir 50₂, thereby retrieving the transport liquid 31 that has been drawn into the transport liquid reservoir 50₂ through the transport liquid retrieval line 82.

At time t2, the liquid transport system 70 repeats the operations performed at time t0.

In the liquid transport system 70, as described above, the valves 72, 76, 80, 84 are selectively opened and closed at prescribed times, while the electroosmotic pump 10₁ and the electroosmotic pump 10₂ are alternately actuated in synchronism with selective opening and closing of the valves 72, 76, 80, 84, to thereby supply or draw the transport liquid 31 to or from the transport liquid supply line 78, and also to fill or retrieve the transport liquid 31 in the transport liquid reservoirs 50₁, 50₂ from the transport liquid filling lines 74, 82. As a result, the transport liquid 31 can continuously be supplied to or drawn from the transport liquid supply line 78.

In each of the above embodiments, the electroosmotic pumps 10A through 10G and the liquid transport system 70 supply the transport liquid 31 to an external device. However, the electroosmotic pumps 10A through 10G and the liquid transport system 70 can also retrieve the transport liquid 31 from an external device, or can be filled with the transport liquid 31 from an external device, by changing the polarities of the DC power supply 34 to thereby draw the drive liquid 15 into the drive liquid reservoirs 52_{I} or into the upstream side of the fluid passage 14. This function is applicable to an automatic blood sampling device, for example, for collecting a blood sample from a small animal.

The liquid transport device and the liquid transport system according to the present invention are not limited to the above-described embodiments, but various other arrangements may be implemented without departing or deviating from the gist of the present invention.

### INDUSTRIAL APPLICABILITY

The liquid transport device according to the present invention is filled with a drive liquid, which exhibits electroosmosis, as well as a transport liquid, which is movable as the drive liquid moves through a liquid isolating means, while remaining out of contact with the drive liquid. The transport liquid can be transported by the liquid transport device, even if the transport liquid is a liquid which does not exhibit electroosmosis. Therefore, the liquid transport device can stably transport the transport liquid irrespective of what type of liquid the transport liquid is, insofar as the drive liquid is a liquid that exhibits electroosmosis. Since the drive liquid and the transport liquid are separated from each other by the liquid isolating means, they are not brought into contact with each other and do not intermix, and thus the transport liquid can be transported reliably.

With the liquid transport system according to the present invention, since a plurality of the above-mentioned liquid transport devices are connected in parallel for supplying or drawing the transport liquid, a large amount of transport liquid can be continuously supplied or continuously drawn.

1. A liquid transport device including a first electrode and a second electrode disposed upstream and downstream, respectively, from an electroosmotic member disposed in a fluid passage, wherein when a voltage is applied to said first electrode and said second electrode, a drive liquid is caused to flow within said fluid passage through said electroosmotic member, characterized in that
at least a portion of an upstream side of said electroosmotic member serves as a drive liquid reservoir filled with said drive liquid;
at least a portion of a downstream side of said electroosmotic member serves as a transport liquid reservoir filled with a transport liquid, which can be supplied to an external device as said drive liquid moves;
a liquid isolating means for isolating said drive liquid and said transport liquid from each other is interposed between said drive liquid and said transport liquid; and
wherein when said voltage is applied, said drive liquid supplies or draws said transport liquid through said liquid isolating means.

2. A liquid transport device according to claim 1, characterized in that
if the fluid passage has a diameter ranging from 2 to 3 mm or less, where surface tension is more dominant than gravitation as a force acting on said drive liquid and said transport liquid within said fluid passage, said liquid isolating means comprises a gas that resides downstream of said electroosmotic member.

3. A liquid transport device according to claim 2, characterized in that
said liquid isolating means is made of a hydrophobic material, which is capable of passing said gas therethrough, while preventing said drive liquid and said transport liquid from passing through said liquid isolating means.

4. A liquid transport device according to claim 1, characterized in that
at least one of said drive liquid reservoir and said transport liquid reservoir comprises a structure that is removable from said liquid transport device.

5. A liquid transport device according to claim 1, characterized in that
said transport liquid reservoir comprises a microfluid chip.

6. A liquid transport system including a plurality of liquid transport devices according to claim 1, comprising:
a plurality of liquid filling lines for filling transport liquid reservoirs of the respective liquid transport devices with said transport liquid;
a plurality of liquid supply lines for supplying the transport liquid from said transport liquid reservoirs to an external device; and
a plurality of valves disposed in said liquid filling lines and said liquid supply lines;
wherein said valves are selectively opened and closed to alternately fill said transport liquid reservoirs with said transport liquid from said liquid filling lines and supply said transport liquid from said transport liquid reservoirs to said liquid supply lines thereby constantly supplying said transport liquid to the external device or constantly drawing said transport liquid from the external device.
